(19) United States
(12) Patent Application Publication
(10) Pub. No.: US 2022/0240367 A1
(43) Pub. Date: Jul. 28, 2022

(54) PACKAGE STRUCTURE HAVING SOLDER MASK LAYER WITH LOW DIELECTRIC CONSTANT AND METHOD OF FABRICATING THE SAME

(71) Applicant: Unimicron Technology Corp., Taoyuan (TW)

(72) Inventors: Ming-Hao WU, Taoyuan (TW); Kuo-Wei LI, Taipei City (TW)

(21) Appl. No.: 17/198,287

(22) Filed: Mar. 11, 2021

(30) Foreign Application Priority Data
Jan. 25, 2021 (TW) 110102738

(51) Int. Cl. H05K 1/02; H05K 3/28; B01J 13/18; B01J 13/20; C09D 11/10

(52) U.S. Cl. CPC H05K 1/024; H05K 3/28; B01J 13/18; H05K 2203/0759; C09D 11/10; H05K 2201/0116; H05K 2203/1333; B01J 13/203

(57) ABSTRACT

A package structure having a solder mask layer with a low dielectric constant includes a substrate, a conductive structure on the substrate, and a solder mask layer on the substrate. The solder mask layer includes bubbles and a solder mask material, wherein the bubbles are disposed within the solder mask layer and the solder mask material covers the bubbles.

### CROSS-REFERENCE TO RELATED APPLICATION

This application claims priority to Taiwan Application Serial Number 110102738 filed Jan. 25, 2021, which is herein incorporated by reference in its entirety.

### BACKGROUND

### Field of Invention

The present disclosure relates to a package structure. More particularly, the present disclosure relates to the package structure having a solder mask layer with a low dielectric constant.

### Description of Related Art

In order to meet the requirement of high-speed and high-frequency transmission of signal, materials applied in printed circuit broads (PCBs) and their corresponding parameters have been developed, such as roughness of metal layer, thickness of substrate, properties of substrate, as so on. Despite of the limitation of process, properties of solder mask layer still can be enhanced.

### SUMMARY

The disclosure provides a package structure having a solder mask layer with a low dielectric constant. The package structure comprises a substrate, a conductive structure on the substrate, and a solder mask layer on the substrate. The solder mask layer comprises bubbles and a solder mask material. The bubbles are disposed within the solder mask layer, and the solder mask material covers the bubbles.

The disclosure provides a method of fabricating a package structure having a solder mask layer with a low dielectric constant. The method comprises forming a spherical shell with a solder mask material and the spherical shell is a hollow structure. The method further comprises forming a mixture of the spherical shell and a liquid solder mask material. The liquid solder mask material is the solder mask material in liquid state. The method further comprises forming a solder mask layer on a substrate with the mixture.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1A is a cross-sectional view of a package structure according to some embodiments of the present disclosure.

FIG. 1B is a cross-sectional view of a package structure according to some embodiments of the present disclosure.

FIG. 2 is a flow diagram of a method for fabricating a package structure according to some embodiments of the present disclosure.

FIG. 3 is a schematic diagram of a method for forming a spherical shell according to some embodiments of the present disclosure.

FIG. 4 is a flow diagram of a method for forming a spherical shell according to some embodiments of the present disclosure.

FIG. 5 is a schematic diagram of forming a spherical shell at one of various process stages according to some embodiments of the present disclosure.

FIG. 6A is a schematic diagram of forming a spherical shell at one of various process stages according to some embodiments of the present disclosure.

FIG. 6B is a cross-sectional view of a spherical shell at one of various process stages according to some embodiments of the present disclosure.

FIG. 7A is a schematic diagram of forming a spherical shell at one of various process stages according to some embodiments of the present disclosure.

FIG. 7B is a cross-sectional view of a spherical shell at one of various process stages according to some embodiments of the present disclosure.

FIG. 8A is a schematic diagram of forming a spherical shell at one of various process stages according to some embodiments of the present disclosure.

FIG. 8B is a cross-sectional view of a spherical shell at one of various process stages according to some embodiments of the present disclosure.

FIG. 8C is an enlarged view of a portion of the spherical shell shown in FIG. 8B according to some embodiments of the present disclosure.

FIG. 9A is a schematic diagram of forming a spherical shell at one of various process stages according to some embodiments of the present disclosure.

FIG. 9B is a cross-sectional view of a spherical shell at one of various process stages according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present disclosure.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

Generally speaking, a dielectric constant (Dk) and a dissipation factor (Df) of a solder mask material used in forming a solder mask/solder resist layer are larger than a Dk and a Df of air. Therefore, the formed solder mask layer would degrade a transmission speed of a signal and a transmission quality of the signal. The present disclosure presents a package structure having the solder mask layer with a low Dk by forming bubbles (e.g., air) within the solder mask layer to reduce the Dk and the Df of the solder mask layer. In addition, a method of fabricating the package structure having the solder mask layer with bubbles is present herein as well.

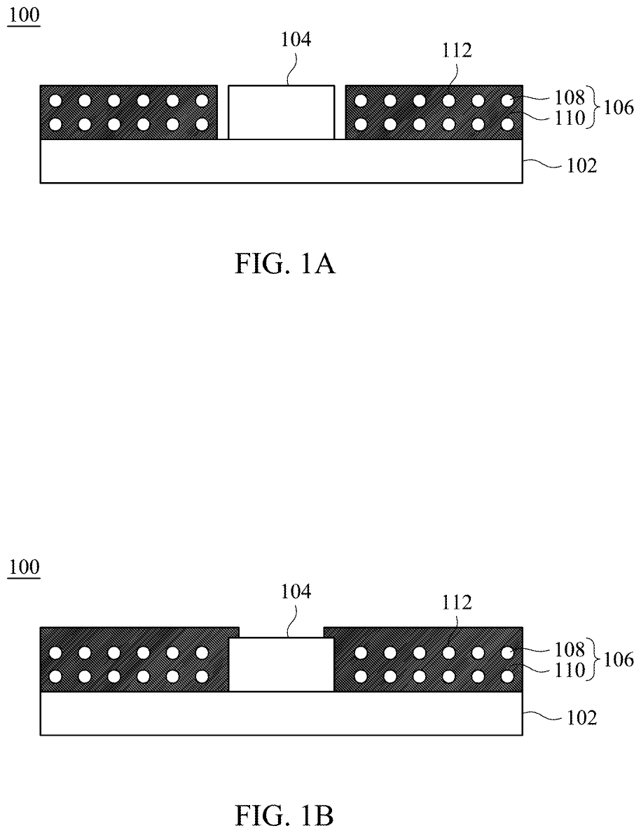

FIG. 1A is a cross-sectional view of a package structure 100 having a solder mask layer with a low Dk according to some embodiments of the present disclosure. The package structure 100 having the solder mask layer with the low Dk includes a substrate 102, a conductive structure 104 formed on the substrate 102, and a solder mask layer 106 formed on the substrate 102. The solder mask layer 106 exposes the conductive structure 104. The solder mask layer 106 includes bubbles 108 disposed inside the solder mask layer 106. The substrate 102 can include polymeric or non-polymeric dielectric materials, such as liquid crystal polymer (LCP), bismaleimide-triazine (BT), prepreg (PP), Ajinomoto build-up film (ABF), epoxy, polyimide (PI), other suitable dielectric material, or combinations of foregoing materials. Further, the above-mentioned dielectric materials can include fibers, such as glass fibers or Kevlar fibers, to reinforce the substrate 102. In some embodiments, the substrate 102 can be formed by photo-imageable dielectric materials or photoactive dielectric materials.

The conductive structure 104 and the solder mask layer 106 are patterned on the substrate 102. In one embodiment, the solder mask layer 106 exposes and is spaced from the conductive structure 104. In some other embodiments shown in FIG. 1B, the solder mask layer 106 exposes and is in physical contact of the conductive structure by covering a portion of the conductive structure 104. Similarly in FIG. 1B, the solder mask layer 106 includes bubbles 108 disposed within the solder mask layer 106.

The conductive structure 104 can be formed by metal such as aluminum (Al), gold (Au), silver (Ag), copper (Cu), tin (Sn), other suitable metal, or combinations of foregoing metals. In some embodiments, the conductive structure 104 is formed by Cu. In some embodiments, the conductive structure 104 is a Cu pad. In some embodiments, the conductive structure 104 is a Cu bump. The patterning process used to form the conductive structure 104 can include one or more deposition processes, one or more photolithography processes, one or more etching processes, any suitable processes, or combinations thereof. The deposition process can include an electroplating process, an electroless plating process, a sputter process, an evaporation process, any suitable techniques, or combination thereof. The conductive structure 104 can further electrically connect other elements (not shown) in the following process.

The solder mask layer 106 includes the bubbles 108 and a solder mask material 110. The bubbles 108 are disposed within the solder mask layer 106. The solder mask material 110 belongs in the solder mask layer 106 excluding the bubbles 108 and covers the bubbles. The bubbles 108 include gas which is within the bubbles 108. The gas varies with an environment of processes. In some embodiments, the bubbles 108 include air.

A diameter of each of the bubbles 108 is less than about 10 μm (micrometer), such as 1, 2, 3, 4, 5, 6, 7, 8, 9 or 10 μm. In some embodiments, the diameter of each of the bubbles 108 is less than 5 μm, such as 1, 2, 3, 4, or 5 μm. A diameter average of the bubbles 108 can be statistically obtained. In some embodiments, a ratio of the diameter of each the bubble 108 to the diameter average of the bubbles 108 is in a range of about 0.8 and about 1.2, such as 0.8, 0.9, 1.0, 1.1, or 1.2. Further, a deviation of each of bubbles 108 between the diameter of each bubble 108 and the diameter average of the bubbles 108 can be statistically obtained. In some embodiments, a ratio of the deviation of each bubble 108 to the diameter average of the bubbles 108 is between about 0 and about 0.2.

Furthermore, an excess of the bubbles may cast a negative impact on solder mask layer 106. For example but not limited to, the bubbles 108 interferes a path of light during photolithography processes, or the bubbles 108 deteriorates a stress of the solder mask layer 106 that can withstand. Therefore, a quantity of the bubbles in the solder mask layer 106 is adjusted. In some embodiments, a volume ratio of the bubbles 108 to the solder mask layer 106 (i.e., a combination of the bubbles 108 and the solder mask material 110) is in a range of about 5 vol.% and about 50 vol.%, such as 5, 10, 15, 20, 25, 30, 35, 40, 45 or 50 vol.%. In some embodiments, a volume ratio of the bubbles 108 to the solder mask layer 106 (i.e., a combination of the bubbles 108 and the solder mask material 110) is in a range of about 5 vol.% and about 10 vol. %, such as 5, 6, 7, 8, 9 or 10 vol. %.

The solder mask material 110 of the solder mask layer 106 includes epoxy, PI, or any suitable materials. Moreover, based on process parameters or product design, additives could be included into the foregoing materials, such as, but not limited to curing agents or photoinitiators. In some embodiments, the solder mask material 110 of the solder mask layer 106 can be a thermal curing solder mask ink. In other embodiments, the solder mask material 110 of the solder mask layer 106 can be a radiation curing solder mask ink. The patterning process used to form the solder mask layer 106 can include deposition process, photolithography process, etching process, screen print process, curing process, any suitable process, or combinations thereof. In some embodiments, the patterned solder mask layer 106 is formed by screen print process. In some embodiments of the method presented in the present disclosure (discuss later), the solder mask material 110 is a homogenous material. In some embodiments, a boundary is formed between the bubbles 108 and the solder mask material 110. Except for the boundary, other heterogeneous boundaries are not observed within the solder mask layer 106.

The volume ratio of the bubbles 108 to the solder mask layer 106 determines an overall Dk and Df of the solder mask layer 106. In some embodiments, as the Dk and Df of the solder mask material 110 are respectively 3.90 and 0.030, and the Dk and Df of air contained within the bubbles 108 are respectively 1.00 and 0.000, a relation between the volume ratio of the bubbles 108 to the solder mask layer 106 and the Dk and Df of the solder mask layer 106 is summarized in below table. The below table shows a negative relation between the volume ratio of the bubbles 108 to the solder mask layer 106 and the Dk and Df of the solder mask layer 106. In another words, an increasing volume ratio of bubbles 108 to the solder mask layer 106 has a benefit of decreasing the Dk and Df of the solder mask layer 106, further forming the solder mask layer 106 with the low Dk.

| | Volume ratio of bubbles to | | | | | |
|---|---|---|---|---|---|---|
| | solder mask layer (vol. %) | | | | | |
| | 0 | 10 | 20 | 30 | 40 | 50 |
| Dk of solder mask layer | 3.90 | 3.61 | 3.32 | 3.03 | 2.74 | 2.45 |
| Df of solder mask layer | 0.030 | 0.027 | 0.024 | 0.021 | 0.018 | 0.015 |

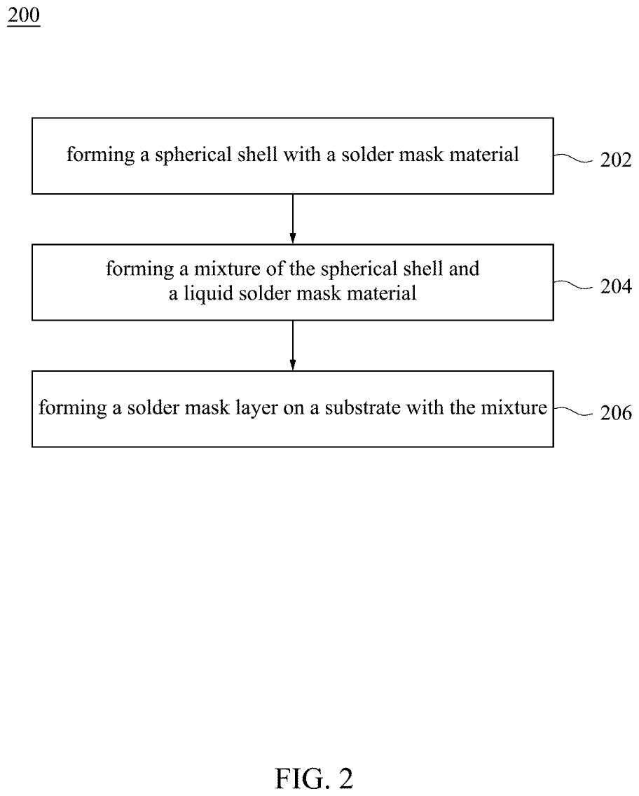

Referring to FIG. 2, a flow diagram of a method 200 for fabricating the package structure 100 according to some embodiments of the present disclosure. Operations in the method 200 can be performed in a different order or not performed depending on specific applications. The method 200 may not produce a complete package structure 100. Accordingly, it is understood that additional processes can be provided before, during, and/or after the method 200, and that some other processes may be briefly described herein.

The method 200 begins with operation 202 and the process of forming a spherical shell with a solder mask material. The spherical shell is a hollow structure. The spherical shell has been cured and therefore it is in solid state. The curing process of spherical shell includes a thermal curing process, a radiation curing process, any other suitable process, or combination of foregoing processes. In some embodiment of the radiation process, ultraviolet (UV) can be applied. Due to the hollow structure, an interior space of the spherical shell includes gas, varying with an environment of processes. In some embodiments, the interior space of the spherical shell includes air. A gas-state space confined within the spherical shell substantially equals to the bubbles 108. Thus, the spherical shell is basically referred to as a former status of the bubbles 108 in FIG. 1A and FIG. 1B. The spherical shell can be formed by a method 300 and a method 400 (discuss later) according to some embodiments of the present disclosure.

Next, in operation 204, a mixture of the spherical shell and a liquid solder mask material is formed and the liquid solder mask material is the solder mask material in liquid state. Therefore, the liquid solder mask material and the solder mask material used to form the spherical sphere are the same. In some embodiments, stirring is performed to achieve a well-mixing mixture of the spherical shell and the liquid solder mask material. As above discussion, since the quantity of the bubbles in the solder mask layer 106 is adjusted and the spherical shell is basically regarded as the former status of the bubbles 108, a volume ratio of the spherical shell to the mixture is correspondingly adjusted. In some embodiments, the volume ratio of the spherical shell to the mixture is adjusted between about 5 vol.% and 50 vol.%, such as 5, 10, 15, 20, 25, 30, 35, 40, 45 or 50 vol.%. In some embodiments, the volume ratio of the spherical shell to the mixture is adjusted between about 5 vol.% and about 10 vol. %, such as 5, 6, 7, 8, 9 or 10 vol. %.

Next, in operation 206, a solder mask layer is formed on a substrate with the mixture the spherical shell and the liquid solder mask material. In some embodiments, a screen print process and a curing process are performed to form an unpatterned solder mask layer on the substrate. An operation number of the screen print process and the curing process is based on process parameters. In some embodiments, a patterning process used to form a patterned solder mask layer (e.g., the solder mask layer 106 in FIG. 1A and FIG. 1B) can include a photolithography process, an etching process, a curing process, any suitable process, or combinations thereof.

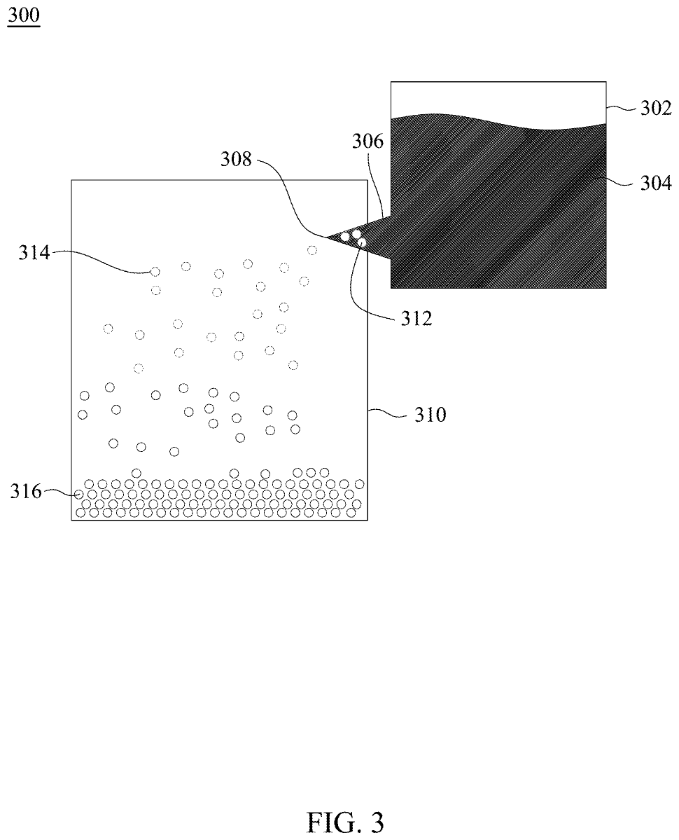

Referring to FIG. 3, a simplified schematic diagram of the method 300 for forming a spherical shell (e.g., operation 202 in the method 200) according to some embodiments of the present disclosure. The method 300 may not produce a complete spherical shell. Accordingly, it is understood that additional processes can be provided before, during, and/or after the method 300, and that some other processes may be briefly described herein. For clarity of discussion, some instruments or systems may be omitted in a simplified schematic diagram (that is, FIG. 3) of the method 300.

In FIG. 3, a first chamber 302 contains a liquid solder mask material 304. The first chamber 302 has a nozzle 306 protruding from the first chamber 302 and inserting into a second chamber 310. An orifice 308 of the nozzle 306 is directed toward an interior space of the second chamber 310. In some embodiments, the nozzle is connected to the first chamber 302 via a pipe (not shown) rather than directly configured on the first chamber 302. The first chamber 302 can have a fluid system (not shown), such as a pump, a piston, any other suitable instrument, or combinations thereof, to drive a flow of the liquid solder mask material 304 toward the nozzle 306. In some embodiments, a piston is used in the first chamber 302 to drive the flow of the liquid solder mask material 304 toward the nozzle 306 within the first chamber 302. After flowing through the orifice 308 of the nozzle 306, the liquid solder mask material 304 enters into the interior space of the second chamber 310.

When the liquid solder mask material 304 passes through the nozzle 306, a pressure drop/flow velocity change of the liquid solder mask material 304 occurs through the nozzle 306. In some embodiments, the pressure drop/flow velocity change of the liquid solder mask material 304 is large enough to from a cavitation phenomenon in the liquid solder mask material 304. In some embodiments, the nozzle 306 has a conical shape, shown as in FIG. 3. That is, a cross-sectional area at an inlet of the nozzle 306 (e.g., an end of the nozzle 306 configured on the first chamber 302) is larger than that at an outlet of the nozzle 306 (e.g., the orifice 308 configured on the second chamber 310).

Due to a sudden shrinking of cross-sectional areas during a course of the liquid solder mask material 304 through the nozzle 306, a flow velocity of the liquid solder mask material 304 is sharply increased and a pressure of the liquid solder mask material 304 is sharply deceased. If the pressure drop/flow velocity change of the liquid solder mask material 304 is large enough to from the cavitation phenomenon, a cavitation bubble 312 is formed in the liquid solder mask material 304. Then, the cavitation bubble 312 becomes a liquid spherical shell 314 after the cavitation bubble 312 along with the liquid solder mask material 304 flows out of the orifice 308 of the nozzle 306 and enters into the interior space of the second chamber 310. The liquid spherical shell 314 is made from the liquid solder mask material 304.

In some embodiments, the second chamber 310 is kept at a temperature to thermally cure the liquid spherical shell 314 as soon as the liquid spherical shell 314 enters into the interior space of the second chamber 310. In some embodiments, the liquid spherical shell 314 is cured and turned into a solid spherical shell. In another words, the liquid spherical shell 314 is cured to form a spherical shell 316 with a hollow structure. In some embodiments, the temperature used in the second chamber 310 is capable of curing the liquid spherical shell 314, such as about 50° C., about 100° C., about 150° C., about 200° C., about 250° C., about 300° C., about 350° C., or about 400° C. In some embodiments, the temperature used to cure the liquid spherical shell 314 in the second chamber 310 is between about 180° C. and about 220° C. In some embodiments, the second chamber 310 is kept at 200° C. to cure the liquid spherical shell 314.

In some other embodiments, the second chamber 310 is provided with radiation to cure the liquid spherical shell 314 as soon as the liquid spherical shell 314 enters into the side of the second chamber 310. In some embodiments, the liquid spherical shell 314 is cured with radiation and turned into a solid spherical shell. In another words, the liquid spherical shell 314 is cured with radiation to form a spherical shell 316 with the hollow structure. In some embodiments, radiation can be UV.

Since the spherical shell 316 has the hollow structure, an interior space of the spherical shell 316 includes gas, varying with an environment of processes. In some embodiments, the interior space of the spherical shell 316 includes air.

Finally, the spherical shell 316 is collected. In some embodiments, the collected spherical shell 316 is further screened for particular sizes. For example, a sieve is used to screen the spherical shell 316. In some embodiments, the spherical shell 316 with a diameter less than about 10 μm is collected by screening. The following operation can be operation 204 in the method 200 after the spherical shell 316 is collected. Based on the disclosure herein, other operations, instruments, or systems used in a similar concept of the method 300 are within the scope and spirit of this disclosure.

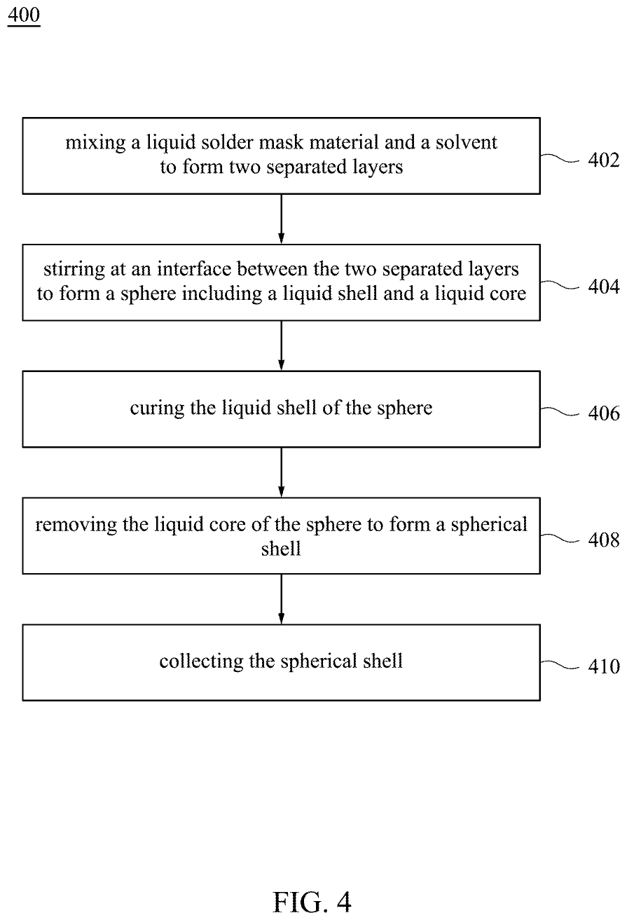

Referring to FIG. 4, a flow diagram of method 400 for forming a spherical shell (e.g., operation 202 in the method 200) according to some embodiments of the present disclosure. Operations in the method 400 can be performed in a different order or not performed depending on specific application. The method 400 may not produce a complete spherical shell. Accordingly, it is understood that additional processes can be provided before, during, and/or after the method 400, and that some other processes may be briefly described herein.

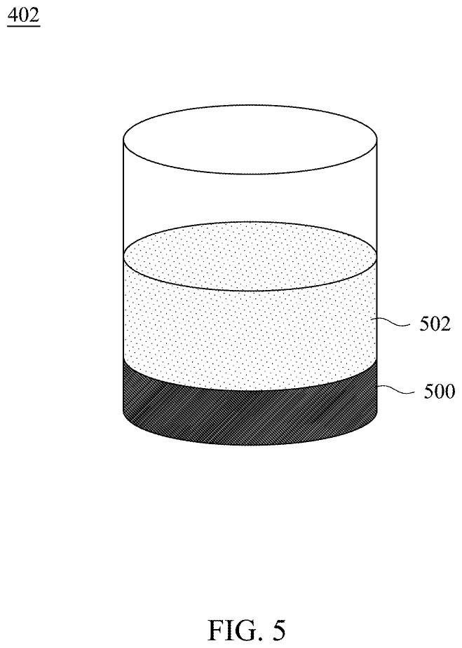

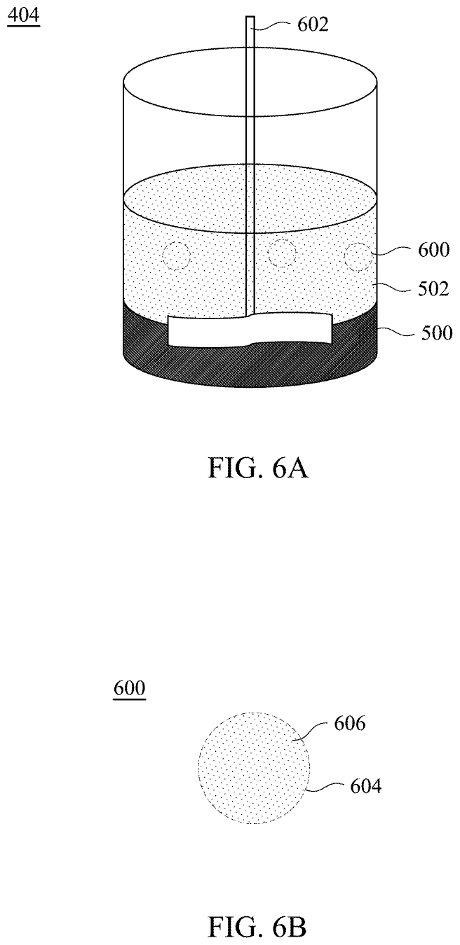

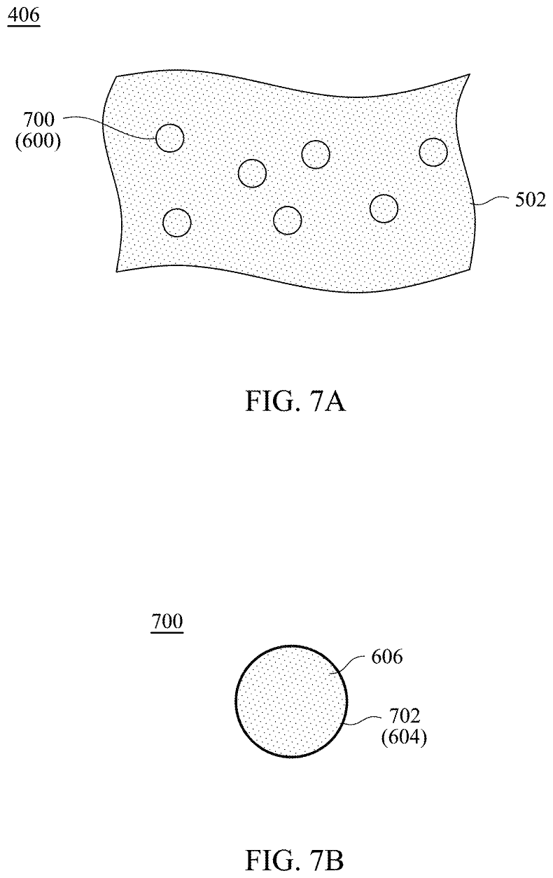

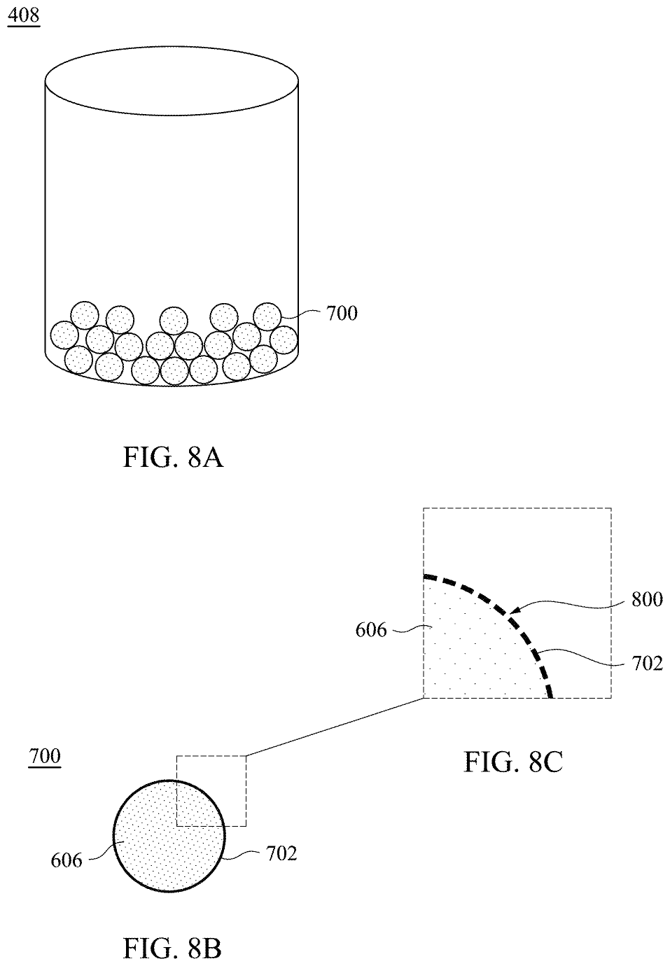

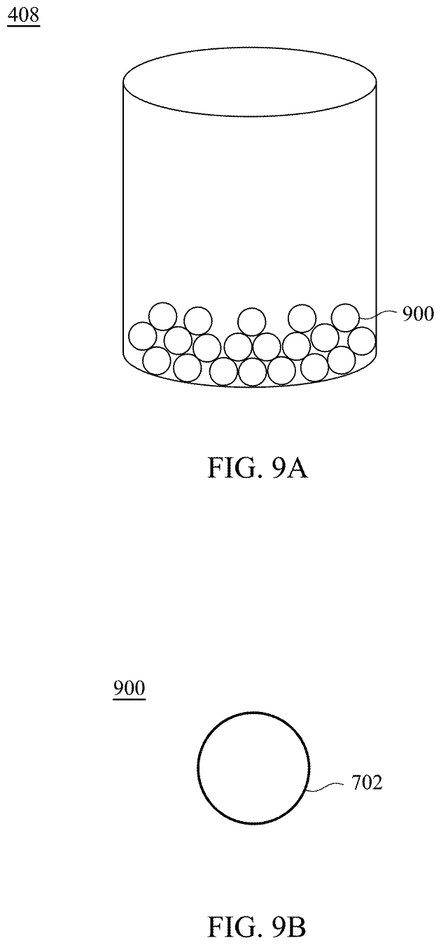

The method 400 for forming the spherical shell will be described in more detail below with reference to FIG. 5, FIG. 6A, FIG. 6B, FIG. 7A, FIG. 7B, FIG. 8A, FIG. 8B, FIG. 8C, FIG. 9A and FIG. 9B. FIG. 5, FIG. 6A, FIG. 7A, FIG. 8A, and FIG. 9A are schematic diagrams of the method 400 at one of various process stages according to some embodiments of the present disclosure. FIG. 6B, FIG. 7B, FIG. 8B, and FIG. 9B are cross-sectional views of the spherical shell at one of various process stages according to some embodiments of the present disclosure. FIG. 8C is an enlarged view of a portion of the spherical shell shown in FIG. 8B according to some embodiments of the present disclosure.

Referring to FIG. 4, the method 400 begins with operation 402 and the process of mixing a liquid solder mask material and a solvent to form two separated layers. Take FIG. 5 as an example, a liquid solder mask material 500 and a solvent 502 are mixed together to form two separated layers because of immiscibility of the liquid solder mask material 500 with the solvent 502. In some embodiments, a formation of two separated layers is due to a difference between a polarity of substances, such as oil and water. Therefore, properties of the liquid solder mask material 500 can determine a selection of the solvent 502. In some embodiments, the solvent 502 is chosen to be polar or with stronger polarity, such as water. In some embodiments, the solvent 502 is chosen to be nonpolar or with weaker polarity, such as hexane.

Referring to FIG. 4, the method 400 continues with operation 404 and the process of stirring at an interface between two separated layers to form a sphere including a liquid shell and a liquid core. For example, as shown in FIG. 6A, a stirring instrument 602 stirs at an interface between the liquid solder mask material 500 and the solvent 502 to distribute a portion of the liquid solder mask material 500 into the solvent 502, and then a sphere 600 can be formed in the solvent 502. The sphere 600 includes a liquid shell 604 and a liquid core 606, as shown in FIG. 6B. In some embodiments, the liquid shell 604 is made of the liquid solder mask material 500, and the liquid core 606 is made of the solvent 502. In some embodiments of the sphere 600, the liquid shell 604 entirely covers the liquid core 606; that is, the liquid solder mask material 500 entirely covers the solvent 502.

Referring to FIG. 4, the method 400 continues with operation 406 and the process of curing the liquid shell of the sphere. For example, as shown in FIG. 7A, the sphere 600 formed in the solvent 502 is cured and turned into a sphere 700 during a curing process. The curing process of the sphere 600 includes a thermal curing process, a radiation curing process, a curing process with additives, any other suitable process, or combination thereof. Referring to FIG. 7B, in some embodiments, the liquid shell 604 is cured and turned into a solid shell 702, and the liquid core 606 is remained its original status (e.g., in liquid state).

A suitable curing temperature is applied in the thermal curing process, such as about 50° C., about 100° C., about 150° C., about 200° C., about 250° C., about 300° C., about 350° C., or about 400° C. In some embodiments of water used in the solvent 502, the curing temperature can be below or equal to about 100° C., such as about 50° C., about 60° C., about 70° C., about 80° C., about 90° C., or about 100° C. In some embodiments of hexane used in the solvent 502, the curing temperature can be below or equal to about 70° C., such as about 50° C., about 60° C., or about 70° C. When a curing temperature of the liquid solder mask material 500 is higher than a boiling temperature of the solvent 502, curing the liquid shell 604 to form the solid shell 702 substantially occurs along with removing the liquid core 606 from the sphere 700. In some embodiments, UV can be used in the radiation curing process to cure the liquid shell 604 turning into the solid shell 702. In some embodiments, curing agents can be used in the curing process with additives to cure the liquid shell 604 turning into the solid shell 702.

Referring to FIG. 4, the method 400 continues with operation 408 and the process of removing the liquid core of the sphere to form the spherical shell. For example, as shown in FIG. 8A, the sphere 700 is left after most of the solvent 502 (with reference of FIG. 7A) is removed. Then, the liquid core 606 of the sphere 700 illustrated in FIGS. 8B and 8C is removed. Approaches of removing the liquid core 606 of the sphere 700 include an evaporation process, a dry process, or combinations thereof. In some embodiments, the evaporation process is performed by increasing a process temperature to evaporate the liquid core 606 of the sphere 700. During the evaporation process, the liquid core 606 vaporized in gas state moves from inside the solid shell 702 to outside the solid shell 702 through pores 800 of the solid shell 702, as shown in FIG. 8C. In some embodiment, the liquid core 606 vaporized in a gas state effuses through the pores 800 of the solid shell 702. In some embodiments, the dry process is performed by using flowing gas, such as flowing air, through the pores 800 to dry the liquid core 606 of the sphere 700. In addition, in some embodiments of the evaporation process, after most of the liquid core 606 is removed due to evaporation, the rest of the liquid core 606 left within the solid shell 702 can further be removed by the dry process.

Referring to FIG. 9A, after the liquid core 606 of the sphere 700 is removed, the remaining solid shell 702 forms a spherical shell 900 with a hollow structure. Specifically speaking, the spherical shell 900 includes the solid shell 702 and gas inside the solid shell 702 as shown in FIG. 9B. The gas varies with an environment of processes. In some embodiments, the spherical shell 900 includes the solid shell 702 and air inside the solid shell 702.

Referring to FIG. 4, the method 400 continues with operation 410 and the process of collecting the spherical shell. For example, the spherical shell 900 (shown in FIG. 9B) is collected. In some embodiments, the collected spherical shell 900 is further screened for particular sizes. For example, a sieve is used to screen the spherical shell 900. In some embodiments, the spherical shell 900 with a diameter less than about 10 μm is collected by screening. The following operation can be operation 204 in the method 200 after the spherical shell 900 is collected. In some embodiments, the method 400 can be an application of microencapsulation technique. Based on the disclosure herein, other operations, instruments, or systems used in a similar concept of the method 400 are within the scope and spirit of this disclosure.

Based on embodiments of the present disclosure, a spherical shell with a hollow structure formed by the method 300 or the method 400 can define a size of bubbles disposed in a solder mask layer in the later process. In another words, a diameter of the spherical shell substantially equals to a diameter of the bubbles. As a result, the size of bubbles can be adjusted by controlling process parameters of forming the spherical shell. Furthermore, the spherical shell and the solder mask layer are formed with the same solder mask material so that the solder mask layer excluding bubbles can be homogenous. That is, except for a boundary between the bubbles and the solder mask material, no other boundaries are observed within the solder mask layer.

The foregoing outlines mixing the spherical shell into the solder mask material and further forming the package structure having the solder mask layer with bubbles. With bubbles (e.g., air) disposed within the solder mask layer, the Dk and the Df of the solder mask layer can be reduced.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

1. A package structure having a solder mask layer with a low dielectric constant, comprising:
a substrate;
a conductive structure on the substrate; and
a solder mask layer on the substrate, the solder mask layer comprising:
a plurality of bubbles, disposed within the solder mask layer; and
a solder mask material, covering the bubbles.

2. The package structure of claim 1, wherein a diameter of each of the bubbles is less than about 10 μm.

3. The package structure of claim 2, wherein a ratio of the diameter of each of the bubbles to a diameter average of the bubbles is between about 0.8 and about 1.2.

4. The package structure of claim 1, wherein a volume ratio of the bubbles to the solder mask layer is between about 5 vol.% and about 50 vol.%.

5. The package structure of claim 1, wherein the solder mask material is homogenous.

6. The package structure of claim 1, wherein the solder mask layer exposes and physically contacts the conductive structure.

7-20. (canceled)
